(19) United States
(12) Patent Application Publication
(10) Pub. No.: US 2023/0361242 A1
(43) Pub. Date: Nov. 9, 2023

(54) DRY TREATMENT FOR SURFACE LOSS REMOVAL IN MICRO-LED STRUCTURES

(71) Applicant: Applied Materials, Inc., Santa Clara, CA (US)

(72) Inventors: Michel Khoury, Mountain View, CA (US); Archana Kumar, Mountain View, CA (US); Jeffrey W. Anthis, San Jose, CA (US); Ryan Ley, Mountain View, CA (US); Alfredo Granados, San Antonio, TX (US)

(73) Assignee: Applied Materials, Inc., Santa Clara, CA (US)

(21) Appl. No.: 17/736,843

(22) Filed: May 4, 2022

(51) Int. Cl. H01L 33/00; H01L 25/075

(52) U.S. Cl. CPC H01L 33/0095; H01L 25/0753; H01L 33/0075

(57) ABSTRACT

A mesa etch may form the geometry of microLED structures. However, the mesa etch may induce defects in the microLED structures that decreases the efficiency of the microLEDs. To correct these defects, a dry etch process may be performed that incrementally removes the surface layers of the microLED structures with the defects. The dry etch may be configured to incrementally remove a small outer layer, and thus may preserve the overall shape of the microLED structures while leaving a smooth surface for the application of a dielectric layer. The dry etch process may include two steps that are repeatedly performed. A first gas may react with the surface to form a gallium compound layer, and a second gas may then selectively remove that layer. The dry etch may include plasma-based etches or reactive thermal etches.

### TECHNICAL FIELD

This disclosure generally describes processes for forming microLED structures. More specifically, this disclosure describes a dry treatment process for removing outer layers in microLED structures that may contain defects.

### BACKGROUND

High-resolution light-emitting diode (LED) displays can include millions of micron-sized pixels arranged to form a viewing screen. For example, microLEDs represent an emerging display technology for flat-panel displays that offer high contrast, response times, and greater energy efficiency than other display types. Micro-LED displays are driven by an array of microscopic LEDs that are arranged to form individual pixel elements.

### SUMMARY

In some embodiments, a method of treating a micro Light-Emitting Diode (microLED) structure may include forming a microLED structure comprising an epilayer of gallium nitride (GaN); performing a mesa etch on the microLED structure; and after performing the mesa etch on the microLED structure, performing a dry etch on the microLED structure to remove a layer from the microLED structure, wherein the layer is less than about 30 nm thick..

In some embodiments, a method of treating a microLED structure may include forming a microLED structure comprising an epilayer of GaN; performing a mesa etch on the microLED structure; and after performing the mesa etch on the microLED structure, performing a plurality of etch cycles. An etch cycle in the plurality of etch cycles may include flowing a first gas to penetrate a surface of the microLED structure and form a layer in the surface of the microLED structure; and flowing a second gas to selectively remove the layer on the surface of the microLED structure.

In some embodiments, 0ne or more non-transitory computer-readable media comprising instructions that, when executed by one or more processors, cause the one or more processors to perform operations including causing a semiconductor processing chamber to form a microLED structure comprising an epilayer of GaN; causing the semiconductor processing chamber to perform a mesa etch on the microLED structure; and after performing the mesa etch on the microLED structure, causing the semiconductor processing chamber to perform a dry etch on the microLED structure to remove a layer from the microLED structure.

In any embodiments, any and all of the following features may be implemented in any combination and without limitation. Performing the mesa etch on the microLED structure may induce crystallographic defects in a surface of the microLED structure, and the defects may cause a non-radiative recombination of currents that reduce the light output of the microLED structure. Performing the dry etch to remove the layer of the microLED structure may remove the crystallographic defects in the surface of the microLED structure. Treating the microLED structure may not use a wet chemical etch to remove the layer from the microLED structure. The microLED structure may be one of a plurality of microLED structures formed on a substrate in a microLED array, and the microLED structures may include a gallium nitride (GaN) epilayer grown on a common substrate. The mesa etch may be performed as a single process for a duration of about 60 seconds to about 120 seconds and using a bias voltage of at least 800 V. The dry etch may use a bias voltage that is at least 10 times less than the bias voltage used by the mesa etch. The first gas may include chlorine and may form a gallium chloride layer as the layer in the surface of the microLED structure; and the second gas may include argon that may sputter away the gallium chloride layer to selectively remove the layer on the surface of the microLED structure. The etch cycle may include an Atomic Layer Etch (ALE) using an inductively coupled plasma (ICP). The first gas may include fluorine and may form a gallium fluoride layer as the layer in the surface of the microLED structure; and the second gas may include trimethyl aluminum that may remove the gallium fluoride layer to selectively remove the layer on the surface of the microLED structure. The etch cycle may include a reactive thermal process that does not require a plasma. The layer on the surface of the microLED structure may be between 1 monolayer and 10 monolayers thick. The etch cycle may include flowing the first gas for between about 1 second and about 4 seconds, and flowing the second gas for between about 2 seconds and about 6 seconds, where the plurality of etch cycles may include at least about 100 cycles. The method/operations may also include maintaining a vacuum environment during the mesa etch and the plurality of etch cycles in a single processing chamber or processing mainframe. The method/operations may also include forming a dielectric layer on the microLED structure with a reflective mirror layer after performing the plurality of etch cycles, where the vacuum environment may be maintained until after the dielectric layer is formed. After performing the plurality of etch cycles, a surface variation of the microLED structure may be less than about 5 nm. An etch cycle in the plurality of etch cycles may include flowing a first gas to penetrate a surface of the microLED structure and form a layer in the surface of the microLED structure; and flowing a second gas to selectively remove the layer on the surface of the microLED structure. The instructions for any of these processes may be stored as recipe, and the one or more processors executing the recipe may be part of a controller for the semiconductor processing chamber.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a top plan view of one embodiment of a processing system of deposition, etching, baking, and curing chambers according to some embodiments.

FIG. 2A illustrates an example of a microLED array that has undergone a mesa etch treatment to generate the individual microLED structures, according to some embodiments.

FIG. 2B illustrates an example of the microLED array after undergoing a wet-etch treatment to compensate for defects induced by the mesa etching process, according to some embodiments.

FIG. 3 illustrates a flowchart of a method for treating a microLED structure, according to some embodiments.

FIG. 4 illustrates a flowchart of a method for treating a microLED structure by performing a particular type of dry etch process, according to some embodiments.

FIGS. 5A-5D illustrate a chlorine and argon dry etch process, according to some embodiments.

FIG. 6 illustrates a microscopic view of a microLED structure after undergoing a mesa etch, according to some embodiments.

FIG. 7 illustrates a microscopic view of a microLED structure after undergoing a standard wet etch treatment, according to some embodiments.

FIG. 8 illustrates a microscopic view of a microLED structure after undergoing a room temperature wet etch treatment, according to some embodiments.

FIG. 9 illustrates a microscopic view of a microLED structure after undergoing a dry etch process, according to some embodiments, according to some embodiments.

FIGS. 10A-D illustrate a more generic flow for the dry-etch process, according to some embodiments, according to some embodiments.

FIG. 11 illustrates an exemplary computer system, in which various embodiments may be implemented.

### DETAILED DESCRIPTION

When forming microLED structures on gallium nitride substrates, a mesa etch may be performed to form the geometry of the microLED structures. However, the mesa etch may induce defects in the surface of the microLED structures that decrease the efficiency and light output of the microLEDs. To correct these defects, a subsequent dry etch process may be performed that incrementally and controllably removes small surface layers of the microLED structures. In contrast to wet etches, the dry etch may be configured to incrementally remove a small outer layer, and thus may preserve the overall shape and geometry of the microLED structures while leaving a smooth and defect-free surface for the subsequent application of a dielectric layer. The dry etch process may include two steps that are alternated and repeatedly performed. A first gas may react with the surface of the structure to form a gallium compound layer on the surface, and a second gas may then selectively remove that layer. The dry etch may include plasma-based etches or reactive thermal etches.

By way of example, many of the processes described herein may be performed in a semiconductor processing chamber. The semiconductor processing chamber may be configured to perform etch processes, such as a mesa etch and/or an Atomic Layer Etch (ALE). The chamber may also be configured to perform other processes, such as processes that grow epilayers of gallium nitride, processes that form dielectric layers on the gallium nitride, and so forth, to form microLED structures and other semiconductor structures. Described below is one semiconductor processing system that may include one or more such chambers where the embodiments described herein may be implemented.

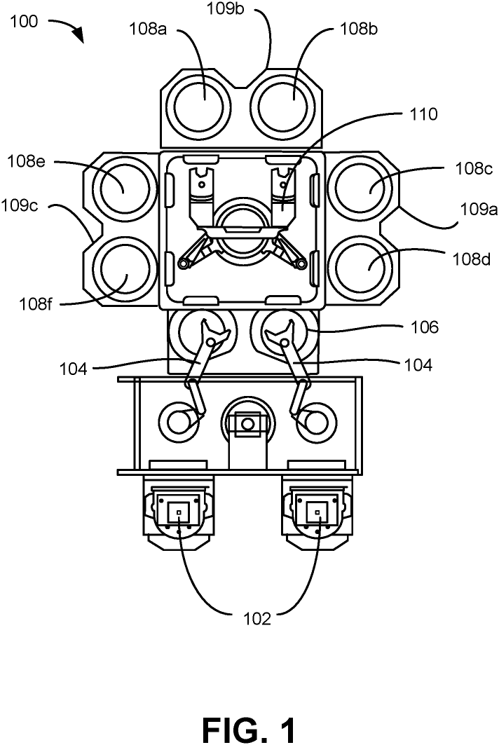

FIG. 1 illustrates a top plan view of one embodiment of a processing system 100 or processing mainframe of deposition, etching, baking, and curing chambers according to some embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by the processing system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

The processing system 100, or more specifically chambers incorporated into the processing system 100 or other processing systems, may be used to produce structures according to some embodiments of the present technology. For example, the processing system 100 may be used to produce microLED arrays by performing operations such as deposition, etch, sputtering, polishing, cleaning, and so forth, in the various substrate processing chambers 108.

Micro Light-Emitting Diodes (microLEDs) are emerging as a power efficient alternative to traditional Liquid Crystal Displays (LCDs) and organic Light-Emitting Diodes (OLEDs). This is particularly true in small, portable electronic devices that are battery-operated and use smaller screen sizes. For example, Augmented Reality (AR) and/or Virtual Reality (VR) applications may use portable electronic headsets with displays that are very small. However, despite their reduced size, these AR/VR displays may require bright, vivid, and precise outputs at a high density in order to deliver the highest quality experience to the user. Traditional LCD and OLED displays may require a relatively large amount of power and can often lack the required output density and precision that may be needed in these applications. Therefore, these technologies are beginning to turn to microLEDs in order to produce the display quality required for mobile applications while maintaining a low-power operational characteristic to preserve battery power. MicroLEDs may be driven brighter at lower current densities than LCD or OLED pixels, often operating at less than 100 A/cm²

When designing smaller displays, individual microLEDs in a microLED array may shrink to increase the pixel density of the array. However, shrinking the sizes of the microLED structures may cause the quantum efficiency of the microLED structures to decrease. Aside from the decreased output per pixel based on simply decreasing the output area of the microLED structure, the smaller structures themselves are less efficient in generating light output. Specifically, when generating the microLED structures, a mesa etch may be used to create the mesa shape of the microLED structures.

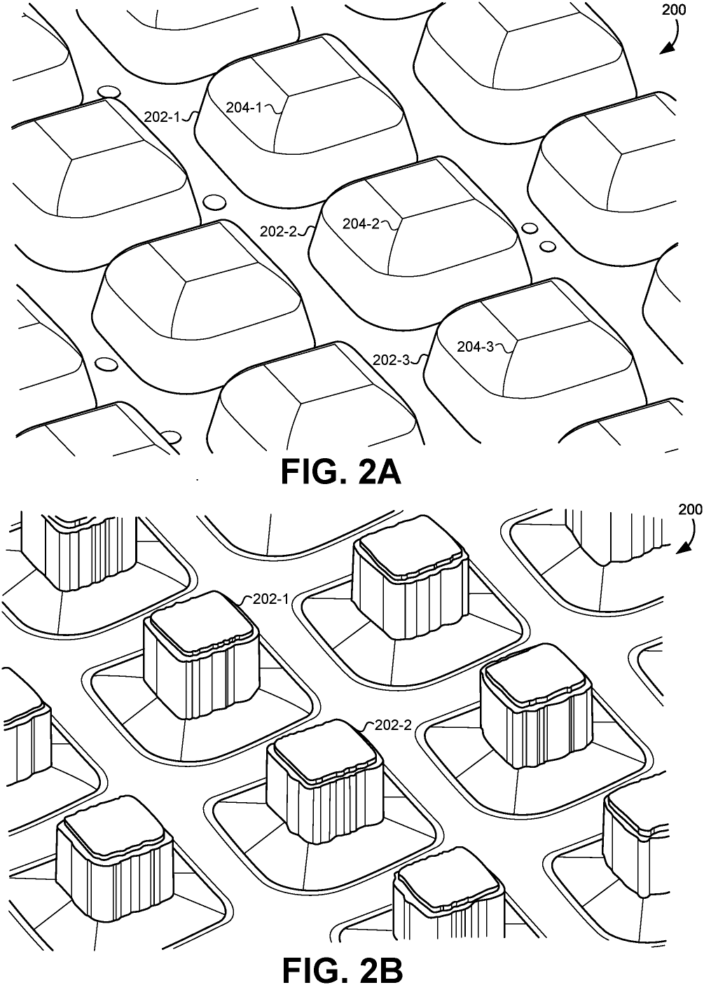

FIG. 2A illustrates an example of a microLED array 200 that has undergone a mesa etch treatment to generate the individual microLED structures 202, according to some embodiments. Using a mesa etch causes a technical problem when forming microLED structures 202. Specifically, the mesa etch process generates a high density of defects in the perimeters of the surface area on top of the microLED structures 202. These defects are crystal defects in nature and are induced by the mesa etch process itself. For example, these crystal defects in the microLED structures cause non-radiative surface recombination currents, where rather than producing photons, the current recombines in a way that does not produce light. These non-radiative areas of the pixel on the pixel are found in FIG. 2A as areas 204 on the edge of each of the microLED structures 202.

FIG. 2B illustrates an example of the microLED array 200 after undergoing a wet-etch treatment to compensate for defects induced by the mesa etching process, according to some embodiments. In order to compensate for the defects on the perimeters of the surface area of the microLED structures 202, a wet potassium hydroxide (KOH) treatment may be applied to the microLED array 200. This wet-etch treatment may use the KOH solution to remove the material containing the defects around the perimeter of the microLED structures 202. However, there are significant drawbacks to using this and other types of wet-etch processes. For example, as illustrated in FIG. 2B, the wet-etch process may significantly change the shape of the microLED structures 202. The KOH etch in particular is an anisotropic, very aggressive wet etch that, while effectively removing the defect regions on the microLED structures 202, may also remove a significant volume of the microLED structures 202. This process may also create rough sidewalls and surfaces on the microLED structures 202. On a larger scale, a wet-etch treatment is difficult to control uniformly across the microLED array 200, causing repeatability and wafer uniformity challenges and further challenges downstream in the manufacturing process.

To solve this and other technical problems involved with removing the defects caused by a mesa etch, some embodiments may replace the wet-etch process (e.g., the KOH chemical etch) with a dry-etch process. Example, instead of using a crystallographic, anisotropic wet KOH etch, these embodiments may instead use a process that specifically targets the plasma-damaged surface on the sidewall and surface of the microLED structures 202. Unlike the wet KOH process that removes both the damaged material and a significant portion of the undamaged material, this process specifically targets the damaged outer layers without significantly affecting the overall shape and geometry of the microLED structures 202. Specifically, some embodiments may use a gentle plasma etch to remove only the damaged outer surface of the gallium nitride (GaN) microLED structures 202 very slowly. This maintains the size and desired shape of the microLED structures 202 using a process that is very controllable and repeatable across the microLED array 200 and across different wafers.

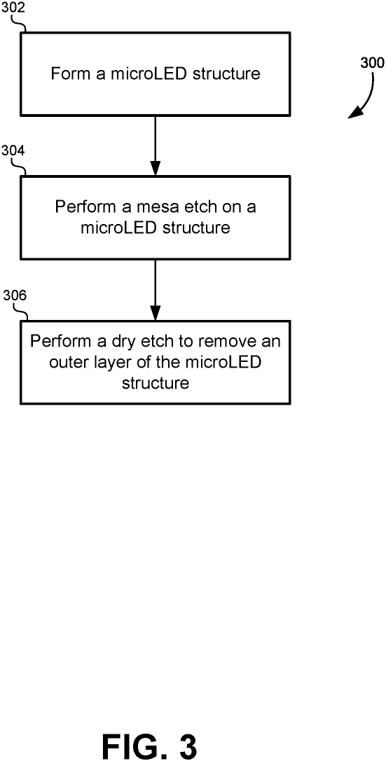

FIG. 3 illustrates a flowchart 300 of a method for treating a microLED structure, according to some embodiments. More specifically, this treatment may include removing an outer layer on the microLED structures, where the outer layer may include crystallographic defects induced by the mesa etch. This method may be carried out in a semiconductor processing chamber, such as an etch chamber as described above. The method may include forming a microLED structure (302). The microLED structure may represent the beginning stages of a microLED pixel before the luminescent material and lens are added. For example, the microLED structure may include a GaN substrate. Additional epilayers of GaN may be grown on the GaN substrate, and portions of GaN epilayers may be n-doped or p-doped to form different regions that may be coupled to electrodes on the microLED structure. Therefore, as used herein, a “microLED structure” may refer specifically to the GaN epilayer that is grown on the substrate. The substrate may be a common substrate that is shared between microLED pixels in an array of microLED pixels. Thus, the microLED structures for the array (e.g., the separate GaN epilayers for each pixel) may be grown on the common substrate.

The method may include performing a mesa etch on the microLED structure (304). The may set may be performed in a single step. In order to maintain an acceptable throughput, the processing time may range between about 60 seconds and about 120 seconds for the substrate, with one embodiment using a processing time of about 80 seconds. The processing chamber may be maintained between about 10 mT and about 30 mT, and the temperature may be maintained at between about 35° C. and about 55° C. Various gases may be provided to the processing chamber during the mesa etch process to generate an Inductively Coupled Plasma (ICP). An example recipe for one mesa etch process is described below in Table 1.

TABLE 1

| Step | Time | Pressure | Bias | Source | Coil | Gas | | | Temp |
|---|---|---|---|---|---|---|---|---|---|
| | (s) | (mT) | (V) | (W) | D/V Cap | CL2 | HBR | BCL3 | DegC |
| Mesa Etch | 80 | 20 | 1000 | 1500 | 35% | 150 | 50 | 50 | 45 |

The mesa etch may be performed to shape the microLED structures illustrated above in FIG. 2A. The mesa etch may be characterized as being performed at a relatively high bias voltage, such as a bias voltage greater than about 600 V, greater than about 800 V, greater than about 1000 V, and greater than about 1200 V. Various embodiments may use different bias voltages including between about 600 V and about 700 V, between about 700 V and about 800 V, between about 800 V and about 900 V, between about 900 V and about 1000 V, between about 1000 V and about 1100 V, between about 1100 V and about 1200 V, and greater than about 1200.

Generally, the greater the bias voltage, the faster the mesa etch may be performed. For example, the mesa etch may be completed in about 80 seconds at a bias voltage of about 1000 V. In order to process a large number of semiconductor substrates at a time, higher voltages may be used to increase the process speed. However, these higher voltages also increase the ion bombardment, and it is believed that the ion bombardment at this high voltage may cause the crystallographic defects in the GaN surface, leading to the microLED efficiency losses. Although reducing the voltage used during the mesa etch process may reduce the damage done by the ion bombardment, this would greatly increase the process time per substrate. Therefore, instead of reducing the bias voltage and increasing the processing time for the mesa etch, some embodiments may instead use a subsequent process to repair the damage done by the mesa etch to the microLED structures.

The method may further include performing a dry etch to remove an outer layer of the microLED structure (306). As described above, previous attempts to repair the defects on the edges of the microLED structures involved using a wet etch, such as a KOH etch to remove a portion of the material. However, the embodiments described herein instead use a dry etch, which is much gentler, controllable, and repeatable across multiple microLED structures and across different wafers. For example, some embodiments may use an Atomic Layer Etch (ALE).

The dry etch may be characterized in comparison to the mesa etch process performed above. For example, the dry etch may use a fraction of the power used during the mesa etch process. For a mesa etch process using a bias voltage of 1500 V, the subsequent dry etch process may use between 10 V and 150 V for various portions of the dry etch process. Thus, the dry etch may be characterized as using between about a 1:150 and about a 1:10 voltage ratio in comparison to the mesa at process. Some embodiments may use different voltage ratio ranges, such as greater than 1:150, between about 1:150 and about 1:125, between about 1:125 and about 1:100, between about 1:100 and about 1:75, between about 1:75 and about 1:50, between about 1:50 and about 1:25, and between about 1:125 and about 1:10.

The dry etch may also be characterized by an amount of material removed from the surface of the microLED structure. For example, the dry etch may remove less than about 30 nm of material. Gentler dry etch processes may remove less than about 25 nm, about 20 nm, about 15 nm, and/or about 10 nm, with different embodiments using ranges of values therein. This may be compared to the mesa etch process, which may remove about 1 µm of material during a full etch cycle.

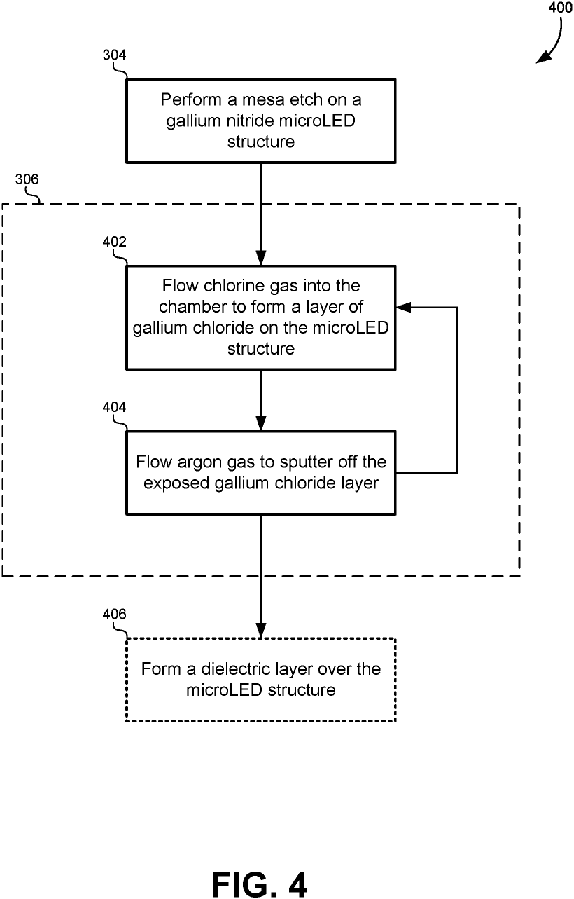

FIG. 4 illustrates a flowchart 400 of a method for treating a microLED structure by performing a particular type of dry etch process, according to some embodiments. The method of flowchart 400 represents one of many different types of dry etch processes that may be performed, and is not meant to be limiting. Flowchart 400 elaborates on step 306 of flowchart 300 in FIG. 3 for performing the dry etch. For example, performing the dry etch may include a cycle of alternating steps performed as part of an ALE process. These steps may be alternated and executed repeatedly until the desired amount of material has been removed. Note that the relatively short duration of each of these steps in comparison to the much longer process of the mesa etch step makes this a very controllable process in comparison.

The method may include flowing chlorine gas into the chamber to form a layer of gallium chloride on the microLED structure (402). This chlorine gas may be used to form an inductively coupled chlorine plasma at a low bias power (e.g., about 10 V) using a relatively high ICP source power (e.g., about 1000 watts). This step may include a constant flow for approximately 1-4 seconds (e.g., about 2 seconds). The chlorine plasma may be used to form a layer of gallium chloride in the surface of the GaN epilayer, such that this layer may be removed during a subsequent step. The gallium chloride layer may be very thin, and may be limited to a small number of atomic layers to tightly control the depth of the atomic layer etch. For example, the gallium chloride layer may be between about 1 monolayer and about 10 monolayers thick.

The method may next include flowing argon gas into the chamber to sputter off the exposed gallium chloride layer generated in the previous step (404). In some embodiments, this step may be slightly longer than the chlorine step running for about 2-6 seconds (e.g., about 3 seconds). For example, the ratio of the time for performing the chlorine step in comparison to the time for performing the argon step may be about 2:3. The bias voltage may be increased during the argon step to about 75-125 V, and an ICP source power may be maintained at between about 800-1200 V (e.g., 1000 V). An example recipe for one dry etch process is described below in Table 2.

TABLE 2

| Step | Time | Pressure | Bias | Source | Coil | Gas | | Temp |
|---|---|---|---|---|---|---|---|---|
| | (s) | (mT) | (V) | (W) | D/V Cap | CL2 | Ar | DegC |
| Cl2 PST | 2 | 20 | 10 | 1000 | 35% | 150 | 0 | 45 |
| AR Active | 3 | 10 | 75-125 | 1000 | 35% | 0 | 100 | 45 |

As illustrated in FIG. 4, step 402 and step 404 may be alternately performed and repeated numerous times. For example, a recipe may specify a number of iterations for which each of these steps will be performed. This number may be selected in order to remove a desired amount of material. It is been discovered that removing approximately 20 nm of surface material can effectively remove a majority of the defects in the microLED structure without significantly altering or degrading the geometry or surface of the structure. This amount of material may be removed by performing the loop of step 402 and step 404 between about 100 iterations and about 250 iterations, depending on the embodiment and operating environment.

In some embodiments, the mesa etch step (304) and the dry etch step (306) illustrated in FIGS. 3-4 may be carried out in the same chamber or in different chambers of the same mainframe processing environment. This may allow the vacuum-sealed environment of the chamber(s) to be present throughout both processes. This provides a technical advantage in that the time required to move the substrate between chambers or mainframe processing environments may be minimized. This additionally prevents the exposure of the microLED structure to a non-vacuum environment. Therefore, the method may optionally include forming a dielectric layer over the microLED structure (406). This dielectric layer may protect the gallium nitride epilayer structure from being exposed to an environment outside of the processing chamber.

It should be appreciated that the specific steps illustrated in FIGS. 3-4 provide particular methods of treating microLED structures according to various embodiments. Other sequences of steps may also be performed according to alternative embodiments. For example, alternative embodiments may perform the steps outlined above in a different order. Moreover, the individual steps illustrated in FIGS. 3-4 may include multiple sub-steps that may be performed in various sequences as appropriate to the individual step. Furthermore, additional steps may be added or removed depending on the particular applications. Many variations, modifications, and alternatives also fall within the scope of this disclosure.

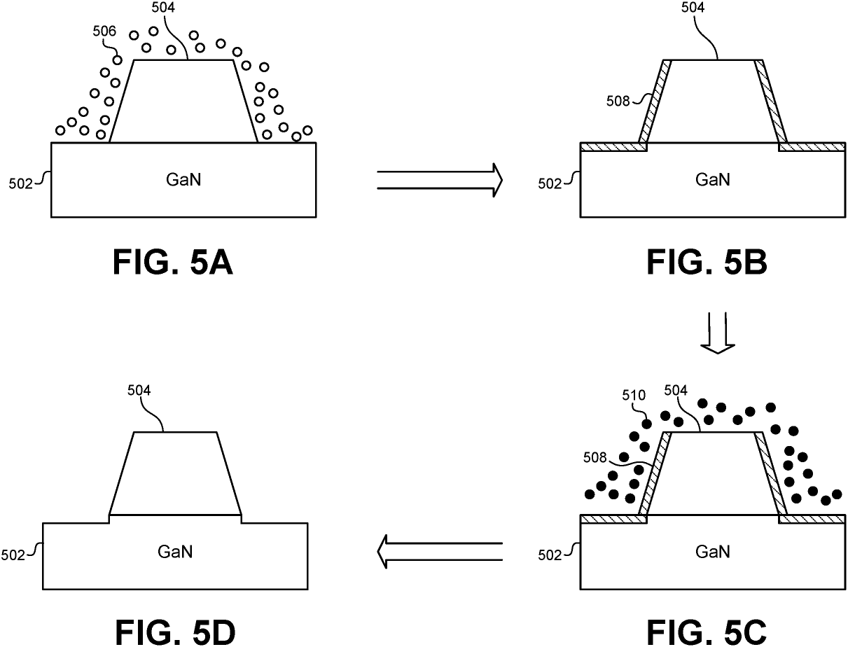

FIGS. 5A-5D illustrate a chlorine and argon dry etch process, according to some embodiments. This process may follow the flowchart 400 of FIG. 4. In FIG. 5A, a gallium nitride substrate 502 may have a gallium nitride epilayer 504 grown on the substrate 502. During the first etch step, chlorine gas 506 may flow into the chamber and be used to form an inductively coupled plasma to react with the surface of the gallium nitride epilayer 504. In FIG. 5B, a thin layer of the gallium nitride epilayer 504 may be converted into a layer of gallium chloride 508. This layer of gallium chloride 508 may be precisely controlled to be only a few atomic layers thick (e.g., between about 1 and 10 monolayers), such that the amount of material removed by the dry etch can be predictably and accurately controlled. In FIG. 5C, argon gas 510 may then be flowed into the chamber and ionized to form an inductively coupled plasma. The argon plasma may gently sputter off the exposed layer of gallium chloride 508. FIG. 5D illustrates the resulting gallium nitride epilayer 504 after the outer layer has been removed by the dry etch process. Note that the thicknesses of the removed layer of gallium chloride 508 are greatly exaggerated in these figures in order to illustrate the process. It should be understood that the thickness of the layer of gallium chloride 508 may be as thin as a single atomic layer.

This process of flowing a first gas into the chamber to form a layer in the surface of the microLEDs structure, then flowing a second gas into the chamber to selectively remove the layer may be repeated until the desired amount of material has been removed. For example, some embodiments may use at least 100 cycles of first flowing the first gas in forming a first plasma, then flowing the second gas informing the second plasma.

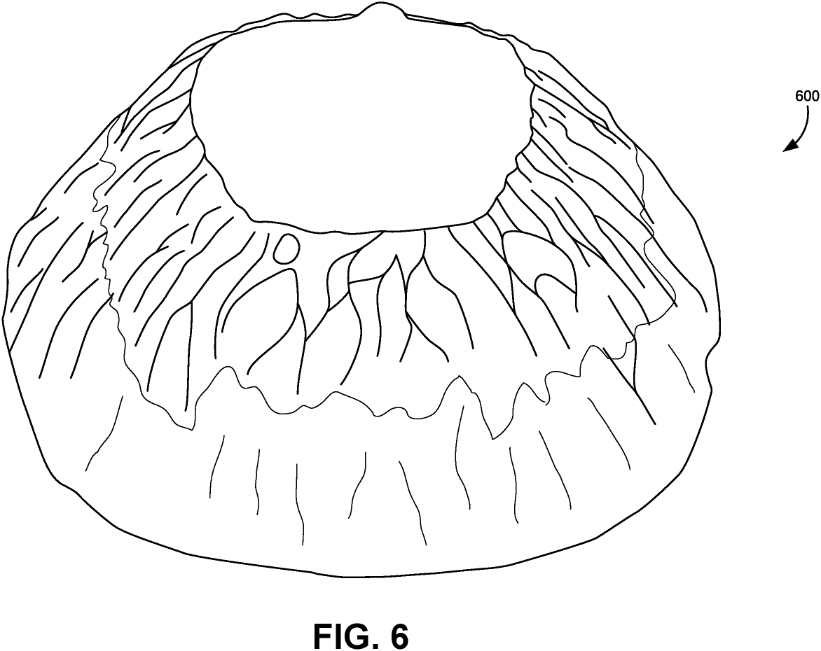

The following figures illustrate the difference between performing a wet (e.g., KOH-based) etch and a dry (e.g., Cl-Ar) etch on a microLED structure. FIG. 6 illustrates a microscopic view of a microLED structure 600 after undergoing the mesa etch described above. This view of the microLED structure 600 may be used as a baseline for comparison between different post-mesa treatments that may be performed. Note that the sidewalls of the microLED structure 600 may include imperfections or ripples that may be due to the ion bombardment of the mesa process itself. Although these figures are not able to show the crystallographic defects that may be formed in the outer layer, the overall shape and smoothness of the sidewalls is useful for comparison.

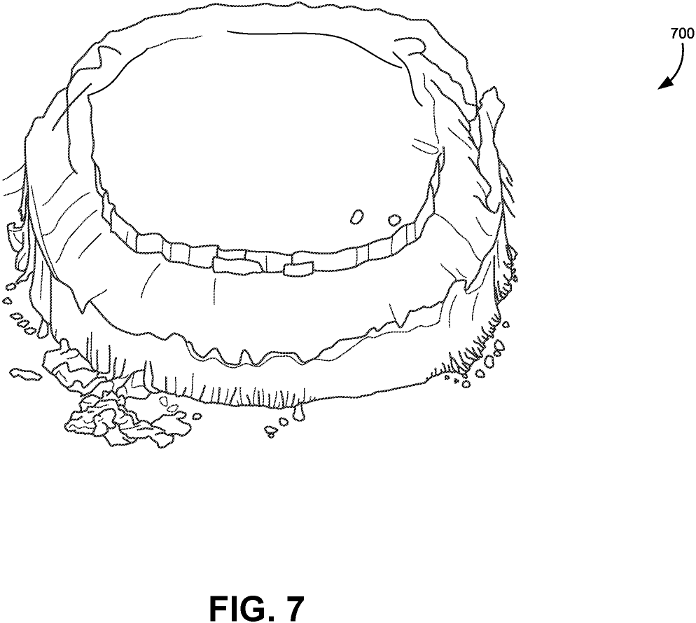

FIG. 7 illustrates a microscopic view of a microLED structure 700 after undergoing a standard wet (e.g. KOH-based) etch treatment. Note that there has been a significant change in the overall shape and geometry of the microLED structure 700. Although the outer layer of material that may include the crystallographic defects induced by the mesa at process has been removed, the resulting microLED structure 700 is significantly different from the baseline microLED structure 600 from FIG. 6.

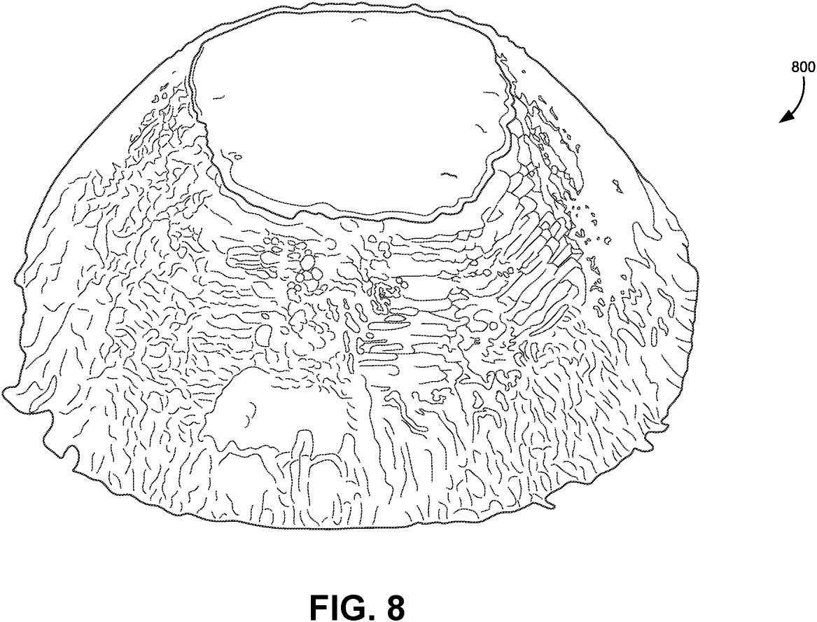

FIG. 8 illustrates a microscopic view of a microLED structure 800 after undergoing a room temperature wet etch treatment. In an effort to improve the wet-etch process, a KOH chemistry may be applied at a lower temperature. It is been discovered that reducing the temperature of the KOH process may affect the roughness of the surface. By reducing the temperature, the amount of structural change caused by the KOH may be reduced. However, note that the sidewalls of the microLED structure 800 now include crystallographic facets (i.e., “ripples”) that have been induced by the KOH process. These crystallographic facets formed on the sidewalls may cause significant problems in downstream manufacturing processes. For example, when integration engineers attempt to form a sidewall dielectric with a reflective mirror layer, the roughness of these crystallographic facets may greatly disrupt the operation of the mirror, particularly at a 300 mm scale. Therefore, while the room-temperature KOH process may perform better than the high-temperature KOH process, the smoothness of the surface of the microLED structure 800 still needs significant improvement.

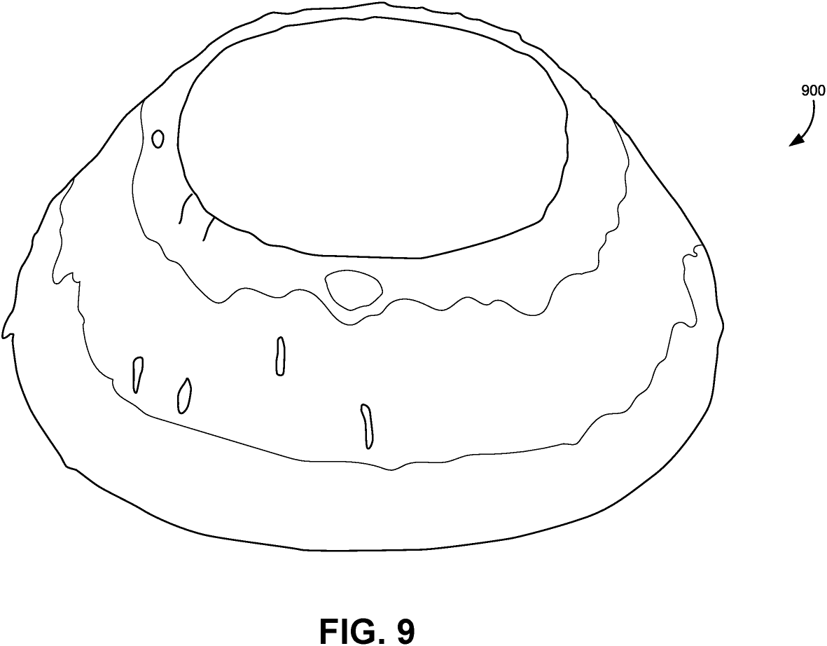

FIG. 9 illustrates a microscopic view of a microLED structure 900 after undergoing a dry etch process, according to some embodiments. For example, the chlorine-argon ALE treatment may have been performed on the microLED structure 600 from FIG. 6 to generate the microLED structure 900 of FIG. 9. Note that the overall shape and geometry of the microLED structure 900 has undergone very little change, due to the precise nature of the ALE process. Additionally, the sidewalls of the microLED structure 900 are relatively smooth in comparison to the wet-etch processes. The difference between the wet-etch process and the more-controlled dry-etch process may be characterized by a difference between the smoothness of the sidewalls of the microLED structure 900. For example, some embodiments using the dry-etch process may have an RMS surface variation of less than about 2 nm, less than about 5 nm, less than about 7 nm, less than about 10 nm, less than about 15 nm, and/or less than about 20 nm. the RMS surface variation of the wet-etch process may be considerably higher than these variations produced by the dry-etch process.

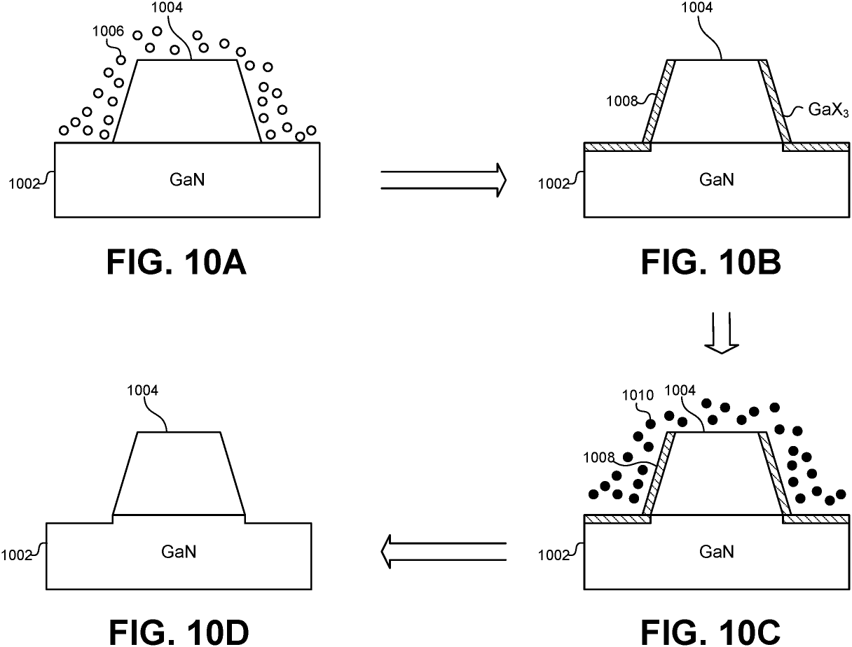

FIGS. 10A-D illustrate a more generic flow for the dry-etch process, according to some embodiments. As described above in step 306 of FIG. 3, the plasma-based dry ALE is only one example of a dry etch that may be used to selectively and controllably remove small layers of the microLED structures after the mesa etch is complete. As an example of one alternative to the plasma-based process, some embodiments may instead use a reactive thermal process to perform the dry etch. Like the ALE process, the thermal process may perform a plurality of etch cycles, with each cycle flowing a first gas into the chamber to form a layer on the GaN surface, then flowing a second gas into the chamber to selectively remove that layer.

FIG. 10A illustrates the substrate 1002 with a epilayer 1004 of gallium nitride forming the microLED structure. A first gas 1006 may be flowed into the chamber. The first gas 1006 may include fluorine, chlorine, bromine, and/or any other halide gas. The first gas 1006 may penetrate the gallium nitride structure to form a gallium halide (e.g., GaX₃) layer 1008. For example, the first gas 1006 may include fluorine, and the gallium halide layer 1008 may be formed as a halogenated gallium surface layer of gallium fluoride.

FIG. 10C illustrates a second phase of the thermal process where a second gas 1010 may be flowed into the chamber. The second gas 1010 may include a number of different gas species, as many different options are available to react with the halogenated gallium surface. For example, some embodiments may use trimethyl aluminum to react with the gallium fluoride layer to create trimethyl gallium an aluminum fluoride, both of which can be flushed from the chamber to leave the attached gallium nitride surface illustrated in FIG. 10D. More generically, this process may create a layer of gallium mixed with another element on the surface of the microLED structure using the first gas 1006, and then the second gas 1010 may be added to the chamber for a reactive thermal process to selectively react with the thin layer formed by the first gas 1006 for removal. In contrast to the ALE process, the reactive thermal process may not require a plasma to be present.

Note that the reactive thermal process may not penetrate as deeply as the plasma-based process. The ion penetration generated by the plasma in the ALE process may penetrate deeper than the reactive chemical process. However, in either process the depth of the etch performed in each cycle may be controlled to be anywhere from a single monolayer to about 10 monolayers. Therefore, different embodiments using any dry-etch process may be characterized by being repeatedly performed in cycles, where each cycle removes a single monolayer, less than about 2 monolayers, less than about 5 monolayers, less than about 7 monolayers, less than about 10 monolayers, and/or less than about 15 monolayers, depending upon the embodiment. Stated another way, the ALE process may be performed cyclically and characterized by a thickness of a removed layer, which depending on the embodiment may remove less than about 2 Å, less than about 5 Å, less than about 7 Å, less than about 10 Å, and less than about 15 Å, depending upon the embodiment.

As described above, these processes for treating microLED structures may be carried out by a processing chamber or processing system or mainframe containing a plurality of processing chambers as described in FIG. 1. These chambers may be controlled by a controller, which may execute a “recipe” that defines instructions for controlling the operating environment inside the chamber. For example, the recipe may be stored as instructions that cause the chamber to maintain or flow specified gas concentrations, provide operating voltages or bias voltages, maintain specified temperatures and/or pressures in the chamber, and so forth. This recipe or set of instructions may be stored on a non-transitory computer-readable medium, and these instructions may be executed by one or more processors in the controller(s) associated with these chambers to perform the methods described above. The following section describes an example computer system that may be used as a central controller, distributed controller, or chamber-specific controller for executing these instructions.

Each of the methods described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user, or may be done automatically by a computer system without human intervention where any determinations are made by a processor. Furthermore, some embodiments of each of the methods described herein may be implemented as a set of instructions stored on a tangible, non-transitory storage medium to form a tangible software product.

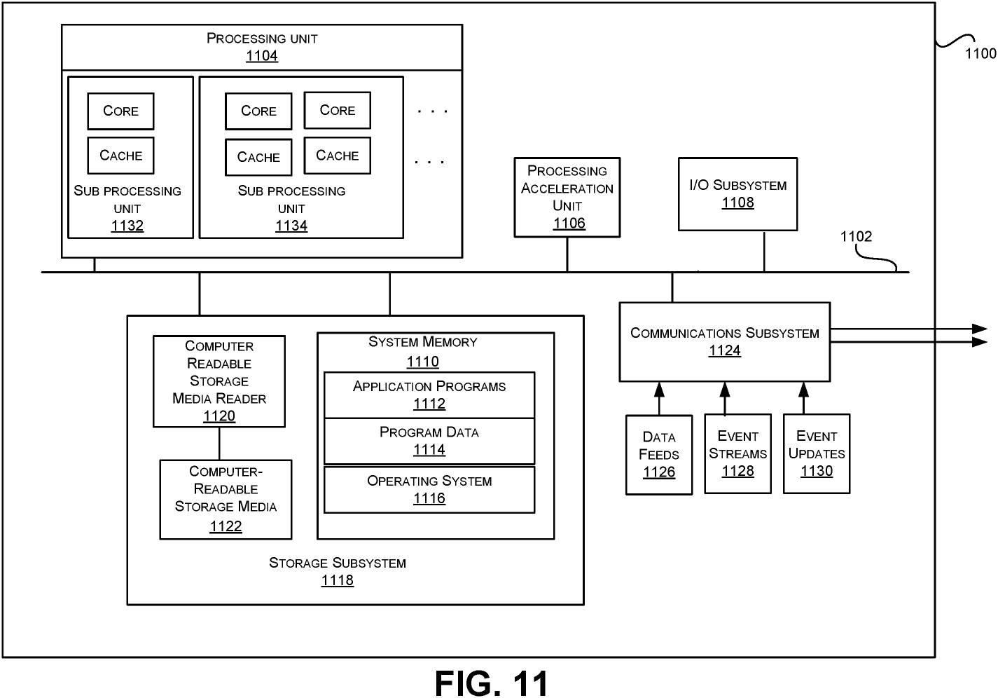

FIG. 11 illustrates an exemplary computer system 1100, in which various embodiments may be implemented. The system 1100 may be used to implement any of the computer systems described above. As shown in the figure, computer system 1100 includes a processing unit 1104 that communicates with a number of peripheral subsystems via a bus subsystem 1102. These peripheral subsystems may include a processing acceleration unit 1106, an I/O subsystem 1108, a storage subsystem 1118 and a communications subsystem 1124. Storage subsystem 1118 includes tangible computer-readable storage media 1122 and a system memory 1110.

Bus subsystem 1102 provides a mechanism for letting the various components and subsystems of computer system 1100 communicate with each other as intended. Although bus subsystem 1102 is shown schematically as a single bus, alternative embodiments of the bus subsystem may utilize multiple buses. Bus subsystem 1102 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 1104, which can be implemented as one or more integrated circuits (e.g., a conventional microprocessor or microcontroller), controls the operation of computer system 1100. One or more processors may be included in processing unit 1104. These processors may include single core or multicore processors. In certain embodiments, processing unit 1104 may be implemented as one or more independent processing units 1132 and/or 1134 with single or multicore processors included in each processing unit. In other embodiments, processing unit 1104 may also be implemented as a quad-core processing unit formed by integrating two dual-core processors into a single chip.

In various embodiments, processing unit 1104 can execute a variety of programs in response to program code and can maintain multiple concurrently executing programs or processes. At any given time, some or all of the program code to be executed can be resident in processor(s) 1104 and/or in storage subsystem 1118. Through suitable programming, processor(s) 1104 can provide various functionalities described above. Computer system 1100 may additionally include a processing acceleration unit 1106, which can include a digital signal processor (DSP), a special-purpose processor, and/or the like.

I/O subsystem 1108 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices such as the Microsoft Kinect® motion sensor that enables users to control and interact with an input device, such as the Microsoft Xbox® 360 game controller, through a natural user interface using gestures and spoken commands. User interface input devices may also include eye gesture recognition devices such as the Google Glass® blink detector that detects eye activity (e.g., ‘blinking’ while taking pictures and/or making a menu selection) from users and transforms the eye gestures as input into an input device (e.g., Google Glass®). Additionally, user interface input devices may include voice recognition sensing devices that enable users to interact with voice recognition systems (e.g., Siri® navigator), through voice commands.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 1100 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 1100 may comprise a storage subsystem 1118 that comprises software elements, shown as being currently located within a system memory 1110. System memory 1110 may store program instructions that are loadable and executable on processing unit 1104, as well as data generated during the execution of these programs.

Depending on the configuration and type of computer system 1100, system memory 1110 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 1104. In some implementations, system memory 1110 may include multiple different types of memory, such as static random access memory (SRAM) or dynamic random access memory (DRAM). In some implementations, a basic input/output system (BIOS), containing the basic routines that help to transfer information between elements within computer system 1100, such as during start-up, may typically be stored in the ROM. By way of example, and not limitation, system memory 1110 also illustrates application programs 1112, which may include client applications, Web browsers, mid-tier applications, relational database management systems (RDBMS), etc., program data 1114, and an operating system 1116. By way of example, operating system 1116 may include various versions of Microsoft Windows®, Apple Macintosh®, and/or Linux operating systems, a variety of commercially-available UNIX® or UNIX-like operating systems (including without limitation the variety of GNU/Linux operating systems, the Google Chrome® OS, and the like) and/or mobile operating systems such as iOS, Windows® Phone, Android® OS, BlackBerry® 10 OS, and Palm® OS operating systems.

Storage subsystem 1118 may also provide a tangible computer-readable storage medium for storing the basic programming and data constructs that provide the functionality of some embodiments. Software (programs, code modules, instructions) that when executed by a processor provide the functionality described above may be stored in storage subsystem 1118. These software modules or instructions may be executed by processing unit 1104. Storage subsystem 1118 may also provide a repository for storing data used in accordance with some embodiments.

Storage subsystem 1100 may also include a computer-readable storage media reader 1120 that can further be connected to computer-readable storage media 1122. Together and, optionally, in combination with system memory 1110, computer-readable storage media 1122 may comprehensively represent remote, local, fixed, and/or removable storage devices plus storage media for temporarily and/or more permanently containing, storing, transmitting, and retrieving computer-readable information.

Computer-readable storage media 1122 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 1100.

By way of example, computer-readable storage media 1122 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 1122 may include, but is not limited to, Zip® drives, flash memory cards, universal serial bus (USB) flash drives, secure digital (SD) cards, DVD disks, digital video tape, and the like. Computer-readable storage media 1122 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 1100.

Communications subsystem 1124 provides an interface to other computer systems and networks. Communications subsystem 1124 serves as an interface for receiving data from and transmitting data to other systems from computer system 1100. For example, communications subsystem 1124 may enable computer system 1100 to connect to one or more devices via the Internet. In some embodiments communications subsystem 1124 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 1124 can provide wired network connectivity (e.g., Ethernet) in addition to or instead of a wireless interface.

In some embodiments, communications subsystem 1124 may also receive input communication in the form of structured and/or unstructured data feeds 1126, event streams 1128, event updates 1130, and the like on behalf of one or more users who may use computer system 1100.

By way of example, communications subsystem 1124 may be configured to receive data feeds 1126 in real-time from users of social networks and/or other communication services such as Twitter® feeds, Facebook® updates, web feeds such as Rich Site Summary (RSS) feeds, and/or real-time updates from one or more third party information sources.

Additionally, communications subsystem 1124 may also be configured to receive data in the form of continuous data streams, which may include event streams 1128 of real-time events and/or event updates 1130, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 1124 may also be configured to output the structured and/or unstructured data feeds 1126, event streams 1128, event updates 1130, and the like to one or more databases that may be in communication with one or more streaming data source computers coupled to computer system 1100.

Computer system 1100 can be one of various types, including a handheld portable device (e.g., an iPhone® cellular phone, an iPad® computing tablet, a PDA), a wearable device (e.g., a Google Glass® head mounted display), a PC, a workstation, a mainframe, a kiosk, a server rack, or any other data processing system.

Due to the ever-changing nature of computers and networks, the description of computer system 1100 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have beeen described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of treating a micro Light-Emitting Diode (microLED) structure, the method comprising:
forming a microLED structure comprising an epilayer of gallium nitride (GaN);
performing a mesa etch on the microLED structure; and
after performing the mesa etch on the microLED structure, performing a dry etch on the microLED structure to remove a layer from the microLED structure, wherein the layer is less than about 30 nm thick.

2. The method of claim 1, wherein performing the mesa etch on the microLED structure induces crystallographic defects in a surface of the microLED structure, and the defects cause a non-radiative recombination of currents that reduce the light output of the microLED structure.

3. The method of claim 2, wherein performing the dry etch to remove the layer of the microLED structure removes the crystallographic defects in the surface of the microLED structure.

4. The method of claim 1, wherein treating the microLED structure does not use a wet chemical etch to remove the layer from the microLED structure.

5. The method of claim 1, wherein the microLED structure is one of a plurality of microLED structures formed on a substrate in a microLED array, and the microLED structures comprise a GaN epilayer grown on a common substrate.

6. The method of claim 1, wherein the mesa etch is performed as a single process for a duration of about 60 seconds to about 120 seconds and using a bias voltage of at least 800 V.

7. The method of claim 1, wherein the dry etch uses a bias voltage that is at least 10 times less than the bias voltage used by the mesa etch.

8. A method of treating a micro Light-Emitting Diode (microLED) structure, the method comprising:
forming a microLED structure comprising an epilayer of gallium nitride (GaN);
performing a mesa etch on the microLED structure; and
after performing the mesa etch on the microLED structure, performing a plurality of etch cycles, wherein an etch cycle in the plurality of etch cycles comprises:
flowing a first gas to penetrate a surface of the microLED structure and form a layer in the surface of the microLED structure; and
flowing a second gas to selectively remove the layer on the surface of the microLED structure.

9. The method of claim 8, wherein:
the first gas comprises chlorine and forms a gallium chloride layer as the layer in the surface of the microLED structure; and
the second gas comprises argon that sputters away the gallium chloride layer to selectively remove the layer on the surface of the microLED structure.

10. The method of claim 9, wherein the etch cycle comprises an Atomic Layer Etch (ALE) using an inductively coupled plasma (ICP).

11. The method of claim 8, wherein:
the first gas comprises fluorine and forms a gallium fluoride layer as the layer in the surface of the microLED structure; and
the second gas comprises trimethyl aluminum that removes the gallium fluoride layer to selectively remove the layer on the surface of the microLED structure.

12. The method of claim 11, wherein the etch cycle comprises a reactive thermal process that does not require a plasma.

13. The method of claim 8, wherein the layer on the surface of the microLED structure is between 1 monolayer and 10 monolayers thick.

14. The method of claim 8, wherein the etch cycle comprises flowing the first gas for between about 1 second and about 4 seconds, and flowing the second gas for between about 2 seconds and about 6 seconds, wherein the plurality of etch cycles comprises at least about 100 cycles.

15. The method of claim 8, further comprising maintaining a vacuum environment during the mesa etch and the plurality of etch cycles in a single processing chamber or processing mainframe.

16. The method of claim 15, further comprising forming a dielectric layer on the microLED structure with a reflective mirror layer after performing the plurality of etch cycles, wherein the vacuum environment is maintained until after the dielectric layer is formed.

17. The method of claim 8, wherein, after performing the plurality of etch cycles, a surface variation of the microLED structure is less than about 5 nm.

18. One or more non-transitory computer-readable media comprising instructions that, when executed by one or more processors, cause the one or more processors to perform operations comprising:
causing a semiconductor processing chamber to form a microLED structure comprising an epilayer of gallium nitride (GaN);
causing the semiconductor processing chamber to perform a mesa etch on the microLED structure; and
after performing the mesa etch on the microLED structure, causing the semiconductor processing chamber to perform a dry etch on the microLED structure to remove a layer from the microLED structure.

19. The one or more non-transitory computer-readable media of claim 18, wherein the dry etch comprises, performing a plurality of etch cycles, wherein an etch cycle in the plurality of etch cycles comprises:
flowing a first gas to penetrate a surface of the microLED structure and form a layer in the surface of the microLED structure; and
flowing a second gas to selectively remove the layer on the surface of the microLED structure.

20. The one or more non-transitory computer-readable media of claim 18, wherein the instructions are stored as recipe, and the one or more processors are part of a controller for the semiconductor processing chamber.
